(19) United States
(12) Patent Application Publication
(10) Pub. No.: US 2026/0314432 A1
(43) Pub. Date: Oct. 8, 2026

(54) METHOD OF MANUFACTURING SEMICONDUCTOR DEVICE

(71) Applicant: Renesas Electronics Corporation, Tokyo (JP)

(72) Inventor: Atsushi SAKAZAKI, Tokyo (JP)

(21) Appl. No.: 19/633,442

(22) Filed: Mar. 30, 2026

(30) Foreign Application Priority Data
Apr. 4, 2025 (JP) 2025-062729

(51) Int. Cl. H10W 70/04; H10W 72/00; H10W 74/01; H10W 90/00

(52) U.S. Cl. CPC H10W 70/048; H10W 70/041; H10W 72/073; H10W 72/075; H10W 74/01; H10W 90/811

(57) ABSTRACT

A method of manufacturing a semiconductor device includes a lead frame preparation step, a sealing step, a half dicing step, a metal film formation step (plating step), and a singulation step. Each of a first lead and a second lead prepared in the lead frame preparation step includes: a first portion having a portion removed by a first blade in the half dicing step; and a second portion that is not removed in the half dicing step. In the singulation step, a tie bar is cut by inserting a second blade between a remaining portion of the first portion of the first lead and a remaining portion of the first portion of the second lead.

### CROSS-REFERENCE TO RELATED APPLICATIONS

The disclosure of Japanese Patent Application No. 2025-062729 filed on Apr. 4, 2025 including the specification, drawings and abstract is incorporated herein by reference in its entirety.

### BACKGROUND

The present invention relates to a method of manufacturing a semiconductor device.

There are disclosed techniques listed below.

Patent Document 1 Japanese Unexamined Patent Application Publication No. 2014-007287

Patent Document 1 discloses a semiconductor device in which a stepped surface is provided on a lower surface of a lead.

### SUMMARY

As a package configuration of a semiconductor device, there is a package in which leads serving as external terminals are exposed from a lower surface of a sealing body. As such a package, for example, there is a Quad Flat Non-leaded package (QFN) type. When a package in which the leads are exposed from the lower surface of the sealing body is mounted on a mounting substrate, the package is mounted by bonding a bonding material such as solder to exposed surfaces of the leads. Further, from the viewpoint of improving visibility of the solder in an inspection after the package is mounted, as in Patent Document 1 described above, there is a method in which a stepped portion is provided at a tip of each lead, thereby forming a solder fillet at the tip of the lead.

However, for example, as the semiconductor device is reduced in size, a spacing between two adjacent leads becomes smaller, and there arises a concern that the two leads may be short-circuited to each other via solder. For example, when each lead is cut by a dicing blade serving as a rotary blade, metal burrs are formed on cut surfaces processed by the blade (particularly, portions located between two adjacent leads). When a length of the metal burr is large, the two adjacent leads may be short-circuited via the metal burr.

Therefore, in order to improve performance of the semiconductor device, there is a need for a technique capable of preventing a short circuit between adjacent leads.

Other objects and novel features will become apparent from the description of this specification and the accompanying drawings.

According to one embodiment, a method of manufacturing a semiconductor device includes steps of: (a) preparing a lead frame including: a first lead provided in a first device formation portion, a second lead provided in a second device formation portion located adjacent to the first device formation portion, and a tie bar provided in a dicing portion between the first device formation portion and the second device formation portion, the tie bar being connected to each of the first lead and the second lead; (b) after the step of (a), mounting a first semiconductor chip on the first device formation portion, and mounting a second semiconductor chip on the second device formation portion; (c) after the step of (b), electrically connecting the first lead and the first semiconductor chip to each other via a first conductive member, and electrically connecting the second lead and the second semiconductor chip to each other via a second conductive member; (d) after the step of (c), forming a sealing body that collectively seals the first lead, the second lead, the tie bar, the first semiconductor chip, the second semiconductor chip, the first conductive member, and the second conductive member such that a lower surface of each of the first lead and the second lead is exposed; (e) after the step of (d), removing a portion of each of the first lead and the second lead using a first blade having a first width greater than a width of the tie bar; (f) after the step of (e), forming a metal film by a plating method on an exposed surface of the lead frame that is exposed from the sealing body; and (g) after the step of (f), removing the tie bar and the sealing body using a second blade having a second width smaller than the first width, thereby separating the first device formation portion and the second device formation portion from each other. The tie bar of the lead frame prepared in the step of (a) includes: a lead connection portion extending in a first direction from the first lead toward the second lead in plan view; and a support portion extending in a second direction intersecting the first direction in plan view. In the step of (a), with an upper surface of each of the first lead and the second lead serving as a reference plane, a height difference between a lower surface of the tie bar and the reference plane is smaller than a height difference between the lower surface of each of the first lead and the second lead and the reference plane. Each of the first lead and the second lead of the lead frame prepared in the step of (a) includes: a first portion having the portion removed by the first blade in the step of (e); and a second portion that is not removed in the step of (e). In the step of (g), the tie bar is cut by inserting the second blade between a remaining portion of the first portion of the first lead and a remaining portion of the first portion of the second lead.

According to the above one embodiment, performance of the semiconductor device can be improved.

### BRIEF DESCRIPTION OF THE DRAWINGS

FIG. 1 illustrates a top view of a semiconductor device according to one embodiment.

FIG. 2 illustrates a bottom view of the semiconductor device illustrated in FIG. 1.

FIG. 3 illustrates a cross-sectional view taken along line A-A in FIG. 1.

FIG. 4 illustrates a perspective plan view illustrating an internal structure of the semiconductor device in a state in which a sealing body illustrated in FIG. 1 is removed.

FIG. 5 illustrates an enlarged cross-sectional view taken along line B-B in FIG. 2.

FIG. 6 illustrates an enlarged cross-sectional view taken along line C-C in FIG. 4.

FIG. 7 illustrates a flowchart illustrating an example of a manufacturing process of the semiconductor device illustrated in FIGS. 1-5.

FIG. 8 illustrates a plan view of a lead frame prepared in a lead frame preparation step illustrated in FIG. 7.

FIG. 9 illustrates an enlarged bottom view of two device formation portions among a plurality of device formation portions illustrated in FIG. 8.

FIG. 10 illustrates an enlarged bottom view of portion D in FIG. 9.

FIG. 11 illustrates an enlarged cross-sectional view taken along line E-E in FIG. 10.

FIG. 12 illustrates an enlarged top view illustrating a state in which semiconductor chips are mounted on the respective device formation portions illustrated in FIG. 9.

FIG. 13 illustrates an enlarged top view illustrating a state in which semiconductor chips and leads illustrated in FIG. 12 are electrically connected via wires.

FIG. 14 illustrates a plan view of a sealing body formed in a sealing step illustrated in FIG. 7.

FIG. 15 illustrates an enlarged cross-sectional view taken along line F-F in FIG. 14, illustrating a state in which a lead frame is arranged in a cavity of a molding die.

FIG. 16 illustrates an enlarged bottom view illustrating a state after completion of a half dicing step illustrated in FIG. 7, in which a sealing body covering a tie bar is removed.

FIG. 17 illustrates an enlarged cross-sectional view taken along line G-G in FIG. 16, illustrating a state in which cutting is being performed by a blade.

FIG. 18 illustrates a schematic explanatory view illustrating an example of a metal film formation step illustrated in FIG. 7.

FIG. 19 illustrates an enlarged bottom view illustrating a state after completion of a singulation step illustrated in FIG. 7, in which two adjacent device formation portions are separated.

FIG. 20 illustrates an enlarged cross-sectional view illustrating a singulation step illustrated in FIG. 7.

FIG. 21 illustrates an enlarged bottom view illustrating a modification of FIG. 10.

FIG. 22 illustrates an enlarged bottom view illustrating leads of a semiconductor device manufactured using a lead frame illustrated in FIG. 21.

FIG. 23 illustrates an enlarged bottom view illustrating another modification of FIG. 10.

### DETAILED DESCRIPTION

Description Format, Basic Terminology, and Usage in Present Application

In present application, description of embodiments is divided into a plurality of sections for convenience. These sections are not independent and separate from each other, and one may constitute a part of details of another, or one may constitute a modification of another. In principle, description of similar portions is omitted to avoid repetition. Each constituent element in embodiments is not necessarily essential unless it is clearly indicated as an essential constituent element, is theoretically limited in number, or is clearly essential from context.

Similarly, in description of embodiments and the like, even when a material or composition is described as “X consisting of A”, elements other than A are not excluded unless clearly limited or clearly limited from context. For example, with respect to a component, such expression means “X including A as a main component”. For example, even when referring to a “silicon member” or the like, it is not limited to pure silicon, and includes a silicon-germanium (SiGe) alloy, a multi-element alloy including silicon as a main component, and a member including other additives. Further, even when referring to gold plating, a Cu layer, nickel plating, and the like, unless otherwise expressly stated, not only pure materials but also members including gold, Cu, nickel, and the like as main components are included.

Furthermore, when referring to specific numerical values or quantities, such specific numerical values are described as examples unless clearly limited or clearly limited from context.

In the drawings of the embodiments, identical or similar portions are denoted by identical or similar symbols or reference numerals, and description thereof is not repeated in principle.

In the accompanying drawings, hatching and the like may be omitted even in cross-sectional views when inclusion thereof would rather make the drawings complicated or when distinction from a void is clear. In this regard, when clear from the description or the like, even for a hole that is closed in a plan view, a contour line of a background may be omitted. Further, even when not illustrated in cross section, hatching or a dot pattern may be provided in order to clearly indicate that a portion is not a void or to clearly indicate a boundary of a region.

### Semiconductor Device

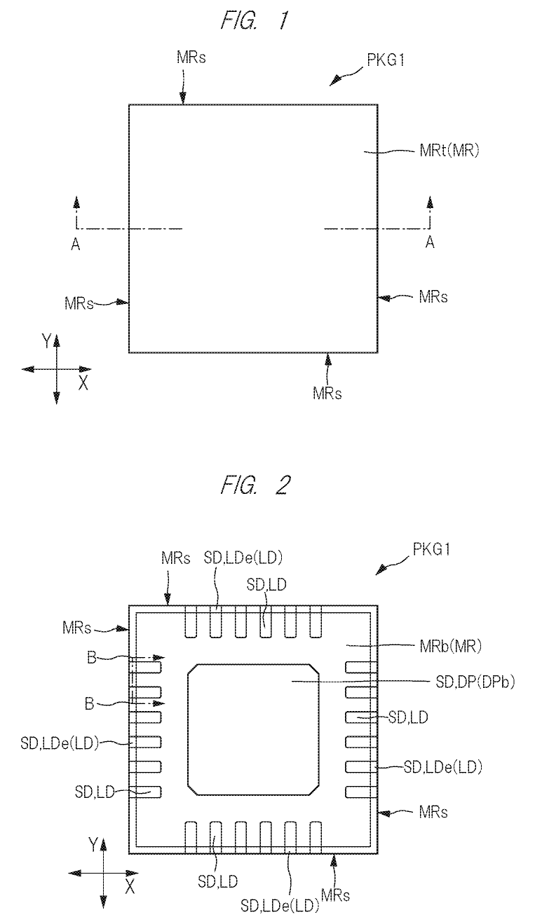

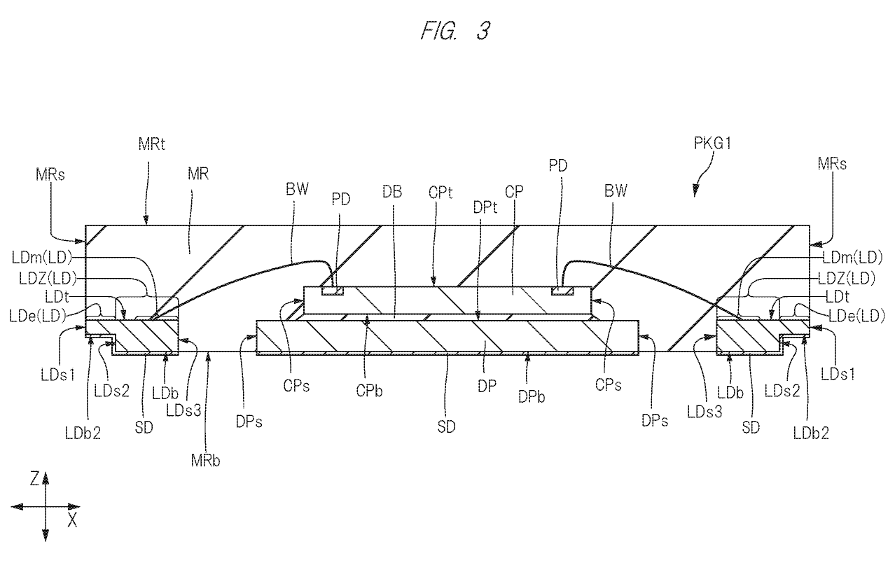

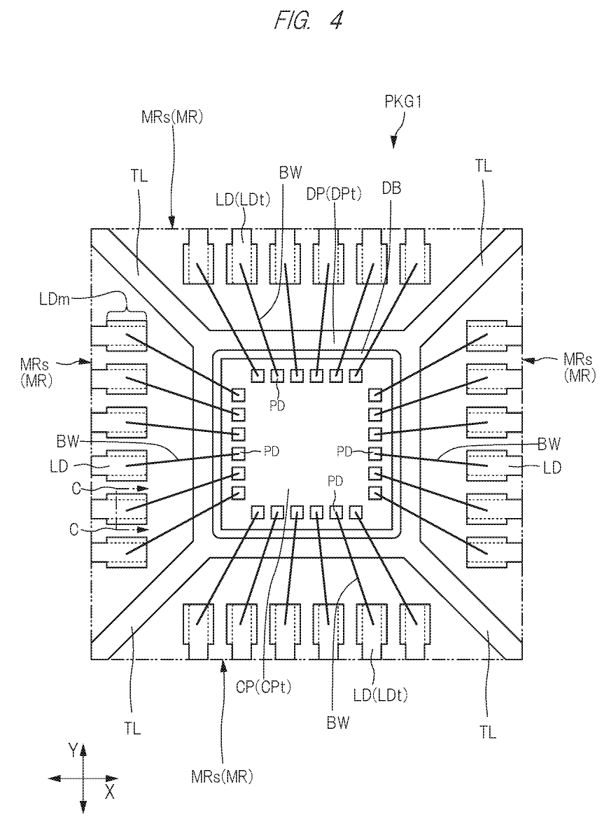

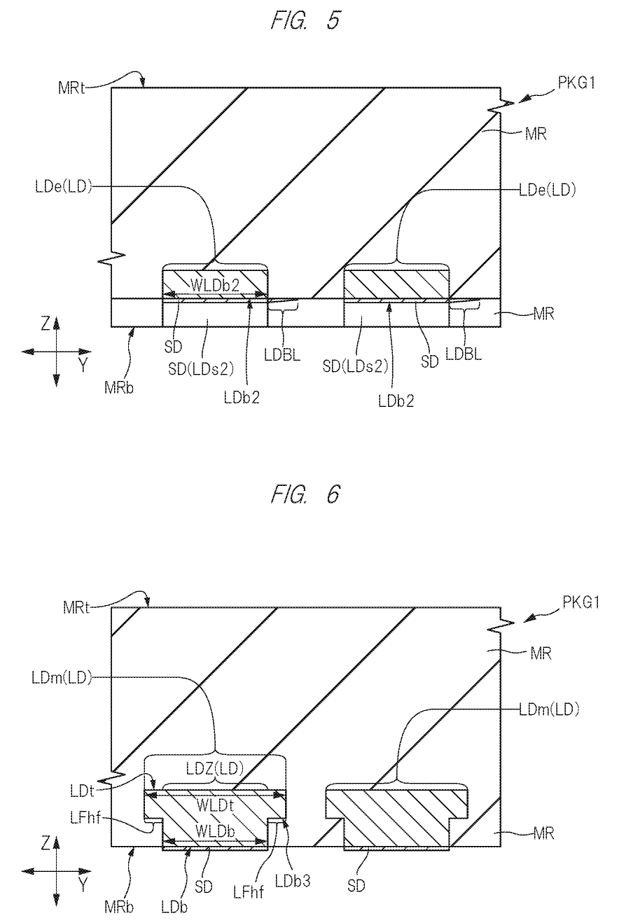

FIG. 1 illustrates a top view of a semiconductor device according to the present embodiment, FIG. 2 illustrates a bottom view of the semiconductor device illustrated in FIG. 1, and FIG. 3 illustrates a cross-sectional view taken along line A-A in FIG. 1. FIG. 4 illustrates a perspective plan view illustrating an internal structure of the semiconductor device in a state in which a sealing body illustrated in FIG. 1 is removed. FIG. 5 illustrates an enlarged cross-sectional view taken along line B-B in FIG. 2. FIG. 6 illustrates an enlarged cross-sectional view taken along line C-C in FIG. 4.

In FIGS. 1-5, at least one of an X direction (see FIGS. 1, 2, 3, and 4), a Y direction (see FIGS. 1, 2, 4, and 5), and a Z direction (see FIGS. 3 and 5) is indicated. The Y direction is a direction intersecting the X direction, and in the following description, the X direction and the Y direction are orthogonal to each other. The Z direction is a direction orthogonal to each of the X direction and the Y direction. In other words, the Z direction is a normal direction (in other words, a vertical direction) with respect to an X-Y plane including the X direction and the Y direction. In the following description, “thickness” means a length in the Z direction in principle. In the following description, “plan view” means a plan view as viewed in the X-Y plane in principle.

A semiconductor device PKG1 according to the present embodiment includes a die pad DP (see FIGS. 3 and 4) and a semiconductor chip CP (see FIGS. 3 and 4) mounted on the die pad DP via a die bond material DB (see FIGS. 3 and 4). The semiconductor device PKG1 further includes a plurality of leads LD arranged around the semiconductor chip CP (die pad DP). The semiconductor device PKG1 includes a plurality of wires (conductive members) BW (see FIGS. 3 and 4) that electrically connect a plurality of pads PD (see FIGS. 3 and 4) of the semiconductor chip CP and the plurality of leads LD, respectively. A plurality of suspension leads TL (see FIG. 4) is connected to the die pad DP. The semiconductor device PKG1 includes a sealing body (resin body) MR that seals the semiconductor chip CP, the plurality of wires BW, and a portion of each of the plurality of leads LD.

A planar shape of the sealing body (resin body) MR illustrated in FIG. 1 is rectangular. The sealing body MR includes an upper surface MRt, a lower surface (back surface, mounting surface) MRb (see FIG. 2) located opposite the upper surface MRt, and side surfaces MRs located between the upper surface MRt and the lower surface MRb. In the example illustrated in FIG. 3, the side surfaces MRs intersect the upper surface MRt and the lower surface MRb. More specifically, in the example illustrated in FIG. 3, the side surfaces MRs are orthogonal to the upper surface MRt and the lower surface MRb.

As illustrated in FIG. 2, in the semiconductor device PKG1, the plurality of leads LD are arranged along the side surfaces MRs of the sealing body MR. The plurality of leads LD is made of a metal material, and in the present embodiment, is made of, for example, copper (Cu) or a copper alloy.

As illustrated in FIG. 4, the plurality of leads LD is arranged around the semiconductor chip CP (in other words, around the die pad DP). Each of the plurality of leads LD is arranged to be spaced apart from the die pad DP. Each of the plurality of leads LD is arranged to be spaced apart from one another.

A plurality of pads PD formed on a front surface CPt of the semiconductor chip CP is electrically connected to the plurality of leads LD via the plurality of wires BW, respectively. The wires BW are made of, for example, gold (Au) or copper (Cu). A portion of each wire BW (for example, one end portion thereof) is bonded to the pad PD, and another portion (for example, the other end portion thereof) is bonded to an upper surface LDt of a wire bonding portion LDm of the lead LD. Although illustration is omitted, a plating film may be formed on a surface (upper surface LDt) of the wire bonding portion LDm of the lead LD. The plating film is made of, for example, silver (Ag) or gold (Au). By forming a plating film made of silver or gold on the surface (upper surface LDt) of the wire bonding portion LDm of the lead LD, bonding strength with the wire BW made of gold or copper can be improved.

As illustrated in FIG. 2, in the plurality of leads LD, a portion of each lead LD (lower surface LDb) is exposed from the sealing body MR at a lower surface MRb of the sealing body MR. A metal film SD is formed on an exposed portion of the lead LD from the sealing body MR, and the lower surface LDb is covered with the metal film SD. The metal film SD is, for example, a plating film formed by a plating method. The metal film SD is made of, for example, a solder material and functions as a bonding material when bonding the lead LD to a terminal on a mounting substrate side described later.

The metal film SD (solder material) of the present embodiment is made of so-called lead-free solder that does not substantially contain lead (Pb). The metal film SD is made of, for example, tin (Sn) alone, tin-bismuth (Sn-Bi), tin-copper-silver (Sn-Cu-Ag), or the like. Here, the lead-free solder means solder having a lead (Pb) content of 0.1 wt% or less. The lead content is defined as a standard in the Restriction of Hazardous Substances (RoHS) Directive. Hereinafter, in the present embodiment, when describing the solder material or a solder component, lead-free solder is referred to unless otherwise expressly stated.

Each of the plurality of leads LD includes a wire bonding portion LDm illustrated in FIG. 4 and a stepped portion (portion, end portion) LDe (see FIG. 2) arranged farther from the die pad DP than the wire bonding portion LDm does. The wire bonding portion LDm is a predetermined region for bonding the wire BW. The wire BW is bonded to any position on the upper surface LDt of the wire bonding portion LDm.

As illustrated in FIG. 3, the wire bonding portion LDm includes the upper surface LDt and the lower surface LDb located opposite the upper surface LDt. The wire BW is connected to the upper surface LDt of the wire bonding portion LDm. The wire bonding portion LDm includes a side surface LDs3 that is a distal end surface of the lead LD on a die pad DP side.

The stepped portion LDe includes the upper surface LDt and a lower surface (stepped surface) LDb2 located opposite the upper surface LDt. A distance from the upper surface LDt to the lower surface LDb2 is shorter than a distance from the upper surface LDt to the lower surface LDb. In other words, when the upper surface LDt is taken as a reference surface, a height difference between the upper surface LDt and the lower surface LDb2 is smaller than a height difference between the upper surface LDt and the lower surface LDb. A thickness of the stepped portion LDe is smaller than a thickness of the wire bonding portion LDm. For example, a thickness of the wire bonding portion LDm illustrated in FIG. 3 (specifically, a thickness of a main body portion LDZ illustrated in FIG. 6 described later) is approximately 150 µm to 200 µm. On the other hand, a thickness of the stepped portion LDe is approximately 75 µm to 100 µm.

At a peripheral portion of the lower surface (mounting surface) of the semiconductor device PKG1, the stepped portion LDe is provided in each of the plurality of leads LD, thereby improving visibility in inspection after mounting. Specifically, when the semiconductor device PKG1 is mounted on a mounting substrate (not illustrated), each of the plurality of leads LD is connected to a terminal on the mounting substrate side via solder.

Here, as a method for confirming a connection state of each of the plurality of leads LD, there is a method of confirming a shape of a solder fillet that connects the lead LD and the terminal on the mounting substrate side. The solder fillet is an inclined surface formed at a peripheral portion of the solder. The solder fillet is formed as the solder wets and spreads on the terminal on the mounting substrate side. Therefore, in a step of mounting the semiconductor device PKG1, when an abnormality such as poor melting of the solder occurs, the shape of the solder fillet becomes abnormal.

The solder fillet is formed at the peripheral portion of the solder. Therefore, even after the semiconductor device PKG1 is mounted on the mounting substrate, the shape of the solder fillet can be easily confirmed by viewing from above the semiconductor device PKG1.

Accordingly, in an appearance inspection after the semiconductor device PKG1 is mounted on a mounting substrate (not illustrated), a method of confirming the shape of the solder fillet is effective. In order to form a solder fillet that is easily visible in the appearance inspection, a height difference between the lower surface LDb and the lower surface LDb2 illustrated in FIG. 3 is preferably large. For example, in the example illustrated in FIG. 3, the thickness of the stepped portion LDe is half or less than half of the thickness of the main body portion LDZ of the lead LD.

The wire bonding portion LDm of the lead LD includes a side surface (lead side surface) LDs3 facing the die pad DP (specifically, a side surface DPs of the die pad DP). In other words, the main body portion LDZ of the lead LD includes the side surface LDs3 facing the die pad DP. The side surface LDs3 is continuous with the upper surface LDt and the lower surface LDb.

The lower surface LDb of the wire bonding portion LDm is continuous with a side surface (lead side surface) LDs2 located opposite the side surface LDs3. In other words, the lower surface LDb of the main body portion LDZ is continuous with the side surface (lead side surface) LDs2 located opposite the side surface LDs3. The side surface LDs2 is continuous with the lower surface LDb2 of the stepped portion LDe.

The stepped portion LDe includes a side surface (lead side surface) LDs1 disposed at a position farthest from the wire bonding portion LDm. The side surface LDs1 is located at a position farthest from the die pad DP among a plurality of lead side surfaces included in each of the plurality of leads LD. The side surface LDs1 is continuous with the upper surface LDt and the lower surface LDb2. As will be described in detail later, the semiconductor device PKG1 is a so-called Mold Array Package (MAP) type semiconductor device. In the MAP-type semiconductor device, in a singulation step described later, the leads LD are cut together with the sealing body MR. Therefore, as illustrated in FIG. 3, the side surface LDs1 is arranged on an extension of the side surface MRs of the sealing body MR. In other words, the side surface MRs and the side surface LDs1 are arranged in the same plane. In other words, in the Z direction, a position of the side surface LDs1 coincides with a position of the side surface MRs. Such a state is referred to as “the side surface LDs1 and the side surface MRs are flush with each other”.

As illustrated in FIG. 5, a metal burr LDBL is connected to the stepped portion LDe of the lead LD. The metal burr LDBL is swarf generated when forming the stepped portion LDe using a blade (dicing blade) in a half dicing step described later. The metal burr LDBL is formed so as to extend along a rotation direction of the blade.

Incidentally, in response to a demand for higher functionality of semiconductor devices, the number of leads LD serving as terminals tends to increase. On the other hand, an increase in a mounting area of the semiconductor device needs to be suppressed. As a result, it is necessary to reduce an arrangement pitch (center-to-center distance) of adjacent leads LD.

When the arrangement pitch of adjacent leads LD becomes small, handling of the metal burr LDBL becomes important from a viewpoint of improving product reliability. For example, even when the arrangement pitch of adjacent leads LD is small, it is necessary to prevent the adjacent leads LD from being short-circuited via the metal burr LDBL.

From a viewpoint of preventing adjacent leads LD from being short-circuited via the metal burr LDBL, it is preferable that a width of the plurality of leads LD in an arrangement direction be small. If the width of the plurality of leads LD in the arrangement direction is small, a separation distance between the leads LD can be increased. As a result, even when the metal burr LDBL is formed, a short circuit between adjacent leads LD can be prevented.

However, when the width of the lead LD is extremely small, the following problem arises in a wire bonding step for bonding the wire BW illustrated in FIG. 3. Specifically, due to positional accuracy of wire bonding, when a width of a predetermined region for bonding the wire becomes small, difficulty of wire bonding increases. Therefore, from a viewpoint of improving connection reliability of the wire BW, the predetermined region for bonding the wire BW needs to have a certain width.

As illustrated in FIG. 6, a width WLDt of the upper surface LDt of the wire bonding portion LDm is greater than a width WLDb of the lower surface LDb. Further, the width WLDb of the lower surface LDb of the wire bonding portion LDm illustrated in FIG. 6 is equal to a width WLDb2 of the lower surface LDb2 of the stepped portion LDe illustrated in FIG. 5. Therefore, the width WLDt of the upper surface LDt of the wire bonding portion LDm illustrated in FIG. 6 is greater than the width WLDb2 of the lower surface LDb2 of the stepped portion LDe illustrated in FIG. 5.

By increasing the width WLDt of the upper surface LDt of the wire bonding portion LDm, the wire BW can be reliably bonded to the upper surface LDt of the wire bonding portion LDm in the wire bonding step.

On the other hand, since the width WLDb2 in the Y direction of the lower surface LDb2 of the stepped portion LDe illustrated in FIG. 5 is small, a separation distance between adjacent leads LD can be increased. Therefore, even when the metal burr LDBL illustrated in FIG. 5 is formed, a short circuit between adjacent leads LD can be suppressed.

In addition to the above measures, with respect to short circuits caused by the metal burr LDBL, there is a measure for shortening a length of the metal burr LDBL in the Y direction. The latter measure will be described later in a section describing a method of manufacturing the semiconductor device.

The wire bonding portion LDm illustrated in FIG. 6 includes a main body portion LDZ and thin portions (half-etched portions) LFhf having a thickness smaller than that of the main body portion LDZ. In the example illustrated in FIG. 6, the main body portion LDZ of the wire bonding portion LDm is arranged between two thin portions LFhf that are spaced apart from each other. As illustrated in FIG. 3, the main body portion LDZ is a portion of the lead LD other than the stepped portion LDe. The main body portion LDZ includes a portion included in the wire bonding portion LDm and a portion arranged between the wire bonding portion LDm and the stepped portion LDe.

A thickness of the thin portion LFhf is smaller than the thickness of the main body portion LDZ. For example, the thickness of the main body portion LDZ illustrated in FIG. 6 is approximately 150 µm to 200 µm. On the other hand, the thickness of the thin portion LFhf is approximately 75 µm to 100 µm.

As will be described in detail later, the stepped portion LDe illustrated in FIG. 3 is obtained by further cutting a lower surface of the thin portion of a lead frame described later. Therefore, a thickness of the stepped portion LDe is smaller than the thickness of the thin portion LFhf illustrated in FIG. 6. In other words, a length from the upper surface LDt to the lower surface LDb2 illustrated in FIG. 3 is shorter than a length from the upper surface LDt to the lower surface LDb3 illustrated in FIG. 6.

The thin portion LFhf is formed by performing half-etching process from a lower surface side of the lead frame. Therefore, when the upper surface LDt of the lead LD is taken as a reference surface, a height difference between the lower surface LDb3 of the thin portion LFhf of the wire bonding portion LDm and the upper surface LDt is smaller than a height difference between the lower surface LDb of the main body portion LDZ of the wire bonding portion LDm and the upper surface LDt.

As illustrated in FIG. 2, a lower surface DPb of the die pad (chip mounting portion, tab) DP is exposed from the sealing body MR at the lower surface MRb of the sealing body MR. The die pad DP is made of a metal material having a higher thermal conductivity than the sealing body MR, and in the present embodiment, is made of, for example, copper (Cu) or a copper alloy. In the example illustrated in FIGS. 2 and 3, a metal film SD that functions as a bonding material at the time of mounting is formed on the lower surface DPb of the die pad DP so as to cover the lower surface of the base material. As described above, the metal film SD is, for example, a plating film (solder film) formed by a plating method.

As illustrated in FIGS. 2 and 4, an upper surface (chip mounting surface) DPt of the die pad DP has a rectangular (quadrilateral) planar shape. In the example illustrated in FIG. 4, an outer size (planar size) of the die pad DP is larger than an outer size (planar size of a back surface CPb) of the semiconductor chip CP. By mounting the semiconductor chip CP on the die pad DP having an area larger than the outer size of the semiconductor chip CP and exposing the lower surface DPb of the die pad DP from the sealing body MR, heat dissipation performance can be improved.

As illustrated in FIGS. 3 and 4, the semiconductor chip CP is mounted on the die pad DP. The semiconductor chip CP is mounted at a center (region including a center) of the die pad DP. As illustrated in FIG. 3, the semiconductor chip CP is mounted on the die pad DP via a die bond material (adhesive) DB in a state in which the back surface CPb faces the upper surface DPt of the die pad DP. In other words, the semiconductor chip CP is mounted by a so-called face-up mounting method in which a front surface (main surface) CPt on which the plurality of pads PD is formed and the chip mounting surface (upper surface DPt) are arranged opposite to each other. The die bond material DB is an adhesive used for bonding the semiconductor chip CP. In the present embodiment, the die bond material DB includes, for example, metal particles made of silver (Ag) or the like contained in an epoxy-based thermosetting resin. However, as a modification of the die bond material DB, solder may be exemplified.

As illustrated in FIG. 4, a planar shape of the semiconductor chip CP mounted on the die pad DP is rectangular. As illustrated in FIG. 3, the semiconductor chip CP includes a front surface (main surface, upper surface) CPt, a back surface (main surface, lower surface) CPb located opposite the front surface CPt, and side surfaces CPs located between the front surface CPt and the back surface CPb.

As illustrated in FIGS. 3 and 4, a plurality of pads (bonding pads) PD is arranged on the front surface CPt of the semiconductor chip CP. In the example illustrated in FIGS. 3 and 4, the plurality of pads PD is arranged along respective sides of the front surface CPt. Although illustration is omitted, a plurality of semiconductor elements (circuit elements) is formed in a main surface of the semiconductor chip CP (specifically, in a semiconductor element formation region provided on an upper surface of a base material (semiconductor substrate) of the semiconductor chip CP). The plurality of pads PD is electrically connected to the semiconductor elements via wirings (not illustrated) formed in a wiring layer arranged inside the semiconductor chip CP (specifically, between the front surface CPt and the semiconductor element formation region not illustrated).

The semiconductor chip CP (specifically, a base material of the semiconductor chip CP) is made of, for example, silicon (Si). An insulating film covering the base material and wirings of the semiconductor chip CP is formed on the front surface CPt, and surfaces of the plurality of pads PD are exposed from the insulating film at openings formed in the insulating film. The pads PD are made of metal, and in the present embodiment, are made of, for example, aluminum (Al) or an alloy layer mainly including aluminum (Al).

As illustrated in FIG. 4, a plurality of suspension leads TL is connected (coupled) to the die pad DP. One end portion of each of the plurality of suspension leads TL is connected to a corner of the die pad DP having a rectangular shape in a plan view. The other end portion of each of the plurality of suspension leads TL extends toward a corner of the sealing body MR. By extending the suspension leads TL toward the corners of the sealing body MR, the suspension leads TL can be arranged without hindering an arrangement of the plurality of leads LD arranged along respective sides (main sides) of the sealing body MR. In this case, the number of terminals (for example, the number of leads LD) of the semiconductor device PKG1 can be increased. Half-etching process is performed on the suspension leads TL from a lower surface side. In the present embodiment, the upper surface, side surfaces, and lower surface of the suspension leads TL are sealed with the sealing body MR. Therefore, as illustrated in FIG. 2, the suspension leads TL (see FIG. 4) are not exposed from the sealing body MR at the lower surface MRb of the sealing body MR.

### Method of Manufacturing Semiconductor Device

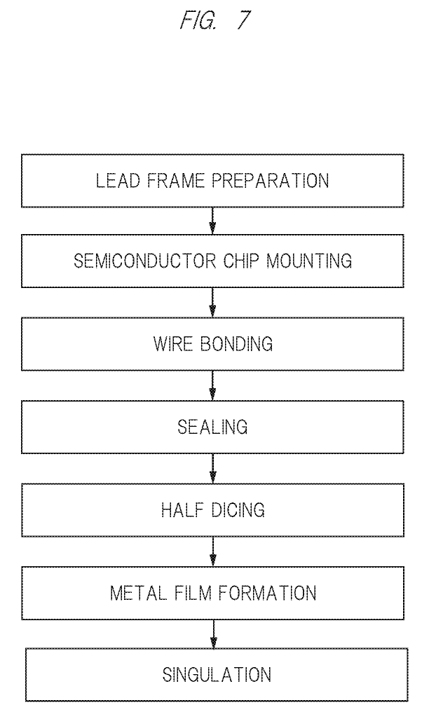

Next, a method of manufacturing the semiconductor device illustrated in FIGS. 1-5 will be described. FIG. 7 illustrates a flowchart illustrating an example of manufacturing steps of the semiconductor device illustrated in FIGS. 1-5. The method of manufacturing the semiconductor device according to the present embodiment illustrated in FIG. 7 includes a lead frame preparation step, a semiconductor chip mounting step, a wire bonding step, a sealing step, a half dicing step, a metal film formation step, and a singulation step.

### Lead Frame Preparation Step

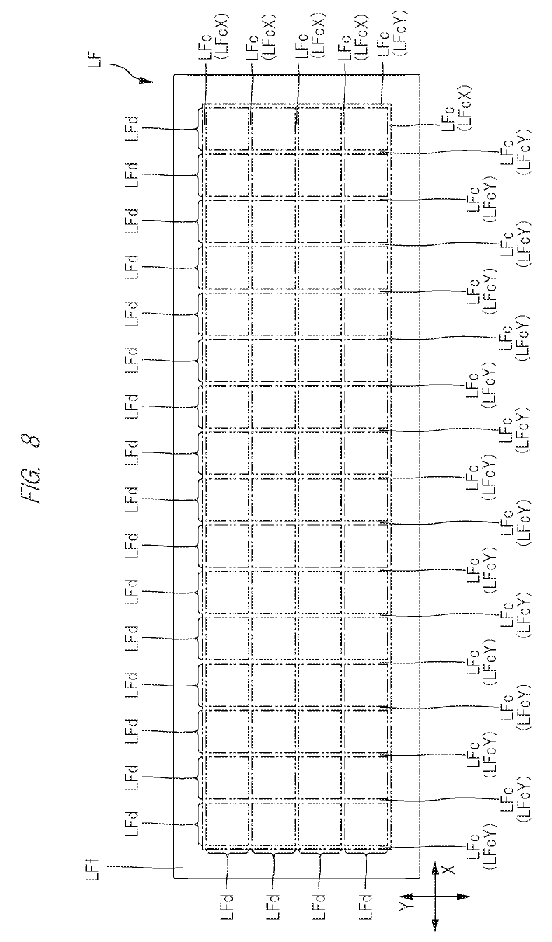

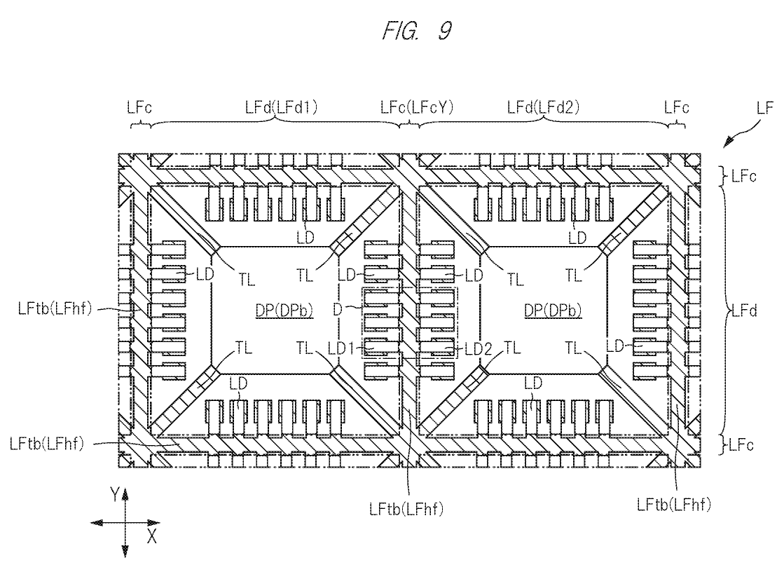

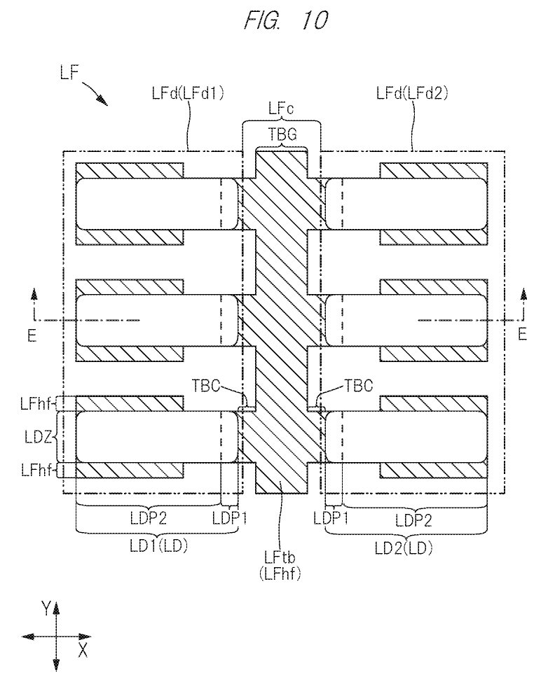

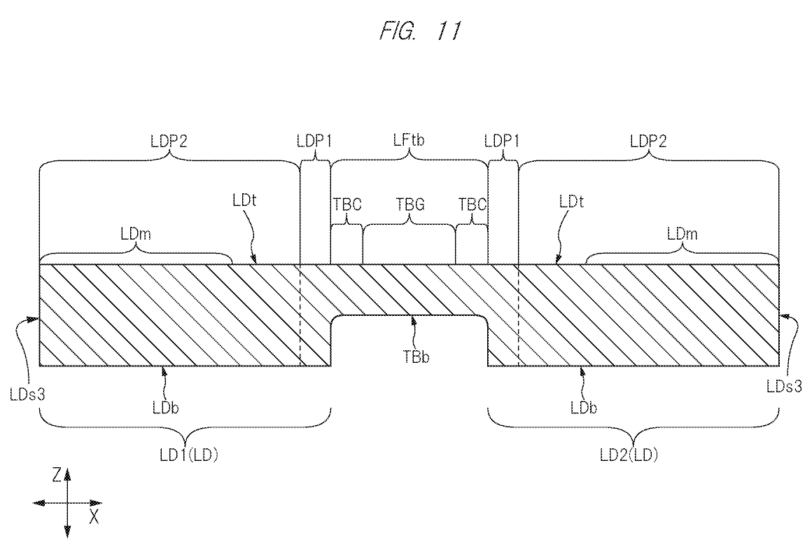

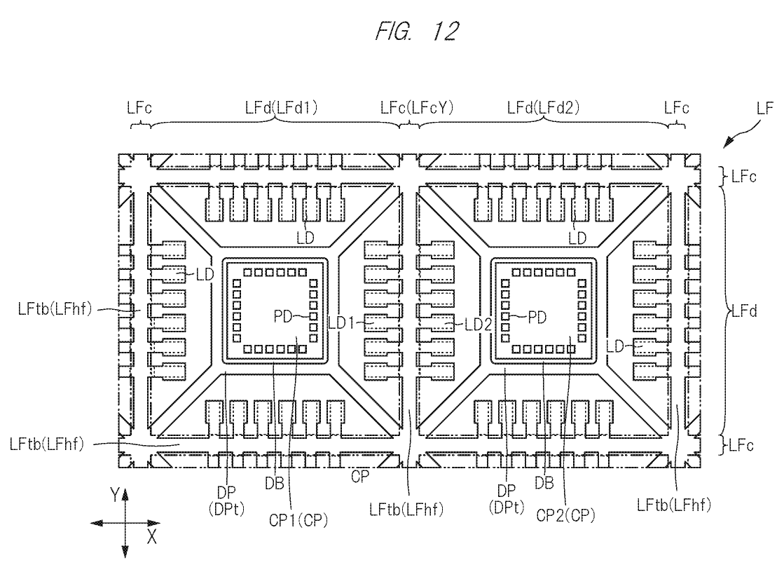

First, in the lead frame preparation step illustrated in FIG. 7, a lead frame LF illustrated in FIGS. 8 to 9 is prepared. FIG. 8 illustrates a plan view of the lead frame prepared in the lead frame preparation step illustrated in FIG. 7. FIG. 9 illustrates an enlarged bottom view of two device formation portions among a plurality of device formation portions illustrated in FIG. 8. FIG. 10 illustrates an enlarged bottom view of portion D in FIG. 9. FIG. 11 illustrates an enlarged cross-sectional view taken along line E-E in FIG. 10.

Although FIGS. 9 and 10 are plan views, the thin portions LFhf are indicated by hatching in order to clearly illustrate a range of portions having a reduced thickness. In FIGS. 10 and 11, a boundary between a portion LDP1 and a portion LDP2 is clearly indicated by a dashed line. However, the dashed lines illustrated in FIGS. 10 and 11 are virtual lines, and in the lead frame LF prepared in this step, the dashed lines illustrated in FIGS. 10 and 11 need not be visually recognizable.

As illustrated in FIG. 8, the lead frame LF prepared in this step includes a plurality of device formation portions LFd connected to a frame portion (frame section) LFf. The lead frame LF further includes dicing portions LFc provided between adjacent device formation portions LFd among the plurality of device formation portions LFd.

The lead frame LF is made of, for example, copper (Cu) or a copper alloy. Each of the plurality of device formation portions LFd is connected to the frame portion LFf. The frame portion LFf has a function of supporting respective members formed in the device formation portions LFd until the singulation step illustrated in FIG. 7.

Each of the plurality of device formation portions LFd corresponds to one semiconductor device PKG1 illustrated in FIG. 1. Each of the plurality of device formation portions LFd includes the die pad DP and a plurality of leads LD arranged to be spaced apart from the die pad DP. The lead frame LF is a so-called multi-device base material in which the plurality of device formation portions LFd is arranged in a matrix. By using the lead frame LF including the plurality of device formation portions LFd in this manner, a plurality of semiconductor devices PKG1 (see FIG. 1) can be manufactured collectively, thereby improving manufacturing efficiency.

The dicing portions LFc are predetermined regions to be cut by a blade in the singulation step illustrated in FIG. 7. The plurality of dicing portions LFc includes a plurality of dicing portions LFcX extending in the X direction and a plurality of dicing portions LFcY extending in the Y direction.

As illustrated in FIG. 9, the dicing portions LFc are formed so as to surround the device formation portions LFd. Tie bars LFtb are arranged in the dicing portions LFc so as to surround the device formation portions LFd. The tie bars LFtb are integrally formed with the plurality of leads LD and the frame portion (frame body) LFf illustrated in FIG. 8.

When distinguishing between the two device formation portions LFd illustrated in FIG. 9, they may be referred to as a device formation portion LFd1 and a device formation portion LFd2. For example, the configuration illustrated in FIG. 9 can be described as follows. The lead frame LF includes the device formation portion LFd1 and the device formation portion LFd2 arranged adjacent to the device formation portion LFd1 in the X direction. The lead frame LF further also includes a dicing portion LFcY arranged between the device formation portion LFd1 and the device formation portion LFd2 and extending in the Y direction.

As illustrated in FIG. 10, the device formation portion LFd1 includes leads LD1. The device formation portion LFd2 includes leads LD2. Each of the leads LD1 and the leads LD2 includes the portion LDP1 from which a portion on a lower surface side is removed in the half dicing step illustrated in FIG. 7 and the portion LDP2 that is not removed in the half dicing step.

A remaining portion of the portion LDP1 that is not removed in the half dicing step constitutes at least a portion of the stepped portion LDe described with reference to FIG. 3. The portion LDP2 illustrated in FIG. 10 includes the wire bonding portion LDm. The portion LDP2 further includes a portion between the portion LDP1 and the wire bonding portion LDm.

As illustrated in FIG. 10, a tie bar LFtb included in the lead frame LF prepared in this step is connected to each of the leads LD1 and the leads LD2. The tie bar LFtb includes lead connection portions TBC and a support portion TBG. In the enlarged plan view illustrated in FIG. 10, the lead connection portion TBC extends in the X direction from the lead LD1 toward the lead LD2. The support portion TBG extends in the Y direction intersecting the X direction. One end portion of the lead connection portion TBC is connected to the lead LD1 (or the lead LD2), and the other end portion is connected to the support portion TBG.

In a portion of the lead frame LF, processing is performed in advance so that a plate thickness becomes smaller. As illustrated by hatching in FIG. 9, the lead frame LF includes a thin portion (half-etched portion) LFhf having a plate thickness smaller than that of the main body portion LDZ of the lead LD. In the example of the present embodiment, the thin portion LFhf is formed by half-etching process, that is, by performing etching processing partway in a thickness direction from the lower surface LDb side of the lead LD.

The thin portion LFhf includes the tie bar LFtb and a portion of the wire bonding portion LDm (a portion other than the main body portion LDZ). Since the tie bar LFtb is subjected to half-etching process in advance, the structure illustrated in FIG. 11 is obtained. That is, in the Z direction, the lower surface TBb of the tie bar LFtb and the lower surface LDb of the lead LD are arranged at different positions. Specifically, when the upper surface LDt of the lead LD1 and the upper surface LDt of the lead LD2 are taken as reference surfaces, a height difference between the lower surface TBb of the tie bar LFtb and the upper surface LDt is smaller than a height difference between the lower surface LDb and the upper surface LDt of each of the lead LD1 and the lead LD2. The upper surface LDt of the lead LD1 and the upper surface LDt of the lead LD2 are arranged at the same height level in the Z direction. The lower surface LDb of the lead LD1 and the lower surface LDb of the lead LD2 are arranged at the same height level in the Z direction.

When the tie bar LFtb is subjected to half-etching process in advance as in the present embodiment, an amount of metal to be cut in the half dicing step illustrated in FIG. 7 can be reduced. The metal burr LDBL described with reference to FIG. 5 extends in proportion to the amount of metal to be cut. Therefore, in the present embodiment, since the amount of metal cut in the half dicing step can be reduced, a length of the metal burr LDBL in the Y direction illustrated in FIG. 5 can be shortened. As a result, it is possible to suppress adjacent leads LD from being short-circuited via the metal burr LDBL.

In the half-etching process, an etching solution (or etching gas) is brought into contact with a processing region of the lead frame LF while a non-processing region of the lead frame LF is covered with a mask. As a result, a portion of the lead frame LF is selectively removed, and the thin portion LFhf is formed. Therefore, even when forming a plurality of thin portions LFhf, it is possible to perform the etching processing collectively.

When the half-etching process is performed in advance, a method may be considered in which the side surface LDs2 continuous with the stepped portion LDe illustrated in FIG. 3 is formed by the half-etching process. In this case, the amount of metal to be cut in the half dicing step illustrated in FIG. 7 can be further reduced. However, from the following viewpoints, it is preferable that the side surface LDs2 be formed by the half dicing step illustrated in FIG. 7.

As described above, as an appearance inspection after mounting the semiconductor device PKG1 described with reference to FIGS. 1 to 6 on a mounting substrate (not illustrated), a method of confirming a solder fillet is effective. As a condition for forming a solder fillet that is easily visible in the appearance inspection, it is important that solder wets and spreads on the side surface LDs2 illustrated in FIG. 3.

Here, in the sealing step illustrated in FIG. 7, the thin portion LFhf (see FIG. 9) of the lead frame LF is sealed with the sealing body. In a method in which the side surface LDs2 illustrated in FIG. 3 is formed by the half-etching process, the side surface LDs2 is also sealed. In this case, it is necessary to remove a portion of the sealing body sealing the side surface LDs2.

As a method of removing a portion of the sealing body, for example, a method of removing it by irradiating a laser may be considered. However, from a viewpoint of improving manufacturing efficiency, it is preferable to perform cutting using a blade, as will be described later as the half dicing step.

However, in cutting using a blade, it is difficult to selectively remove only the sealing body. Therefore, from a viewpoint of exposing the side surface LDs2 illustrated in FIG. 3 from the sealing body MR, it is preferable to form the side surface LDs2 illustrated in FIG. 3 by cutting the portion LDP1 of the lead LD illustrated in FIG. 11.

### Semiconductor Chip Mounting Step

In the semiconductor chip mounting step illustrated in FIG. 7, as illustrated in FIG. 12, the semiconductor chips CP are mounted on the die pads DP via the die bond material DB. FIG. 12 illustrates an enlarged top view illustrating a state in which semiconductor chips are mounted on respective device formation portions illustrated in FIG. 9. The semiconductor chip CP is mounted on the die pad DP included in each of the plurality of device formation portions LFd illustrated in FIG. 12. In other words, in this step, a semiconductor chip CP1 is mounted on the device formation portion LFd1, and a semiconductor chip CP2 is mounted on the device formation portion LFd2.

In this step, as illustrated in FIG. 3 described above, the semiconductor chip CP is mounted on the die pad DP in a state in which the back surface CPb of the semiconductor chip CP and the upper surface DPt of the die pad DP face each other.

In this step, for example, the semiconductor chip CP is mounted via the die bond material DB, which is an epoxy-based thermosetting resin. Before being cured (thermally cured), the die bond material DB is a paste material having fluidity. When such a paste material is used as the die bond material DB, first, the die bond material DB is applied to the die pad DP, and thereafter, the back surface CPb of the semiconductor chip CP is bonded to the upper surface DPt of the die pad DP. After bonding, the die bond material DB is cured (for example, by performing heat treatment), whereby, as illustrated in FIG. 3, the semiconductor chip CP is fixed on the die pad DP via the die bond material DB.

In this step, the die bond material DB and the semiconductor chip CP are respectively arranged on the die pad DP provided in each of the plurality of device formation portions LFd. Then, the semiconductor chip CP is mounted on each of the device formation portions LFd.

In the present embodiment, a configuration in which a paste material made of a thermosetting resin is used as the die bond material DB has been described; however, various modifications may be applied. For example, solder may be used as the die bond material DB.

As a modification in which solder is used as the die bond material DB, in this step, a paste material containing a solder component (solder paste) is used as the above-described paste material. When the solder paste is used, the die bond material DB is formed by performing a reflow process in which the die bond material DB is heated to a temperature equal to or higher than a melting temperature of the solder and then cooled.

### Wire Bonding Step

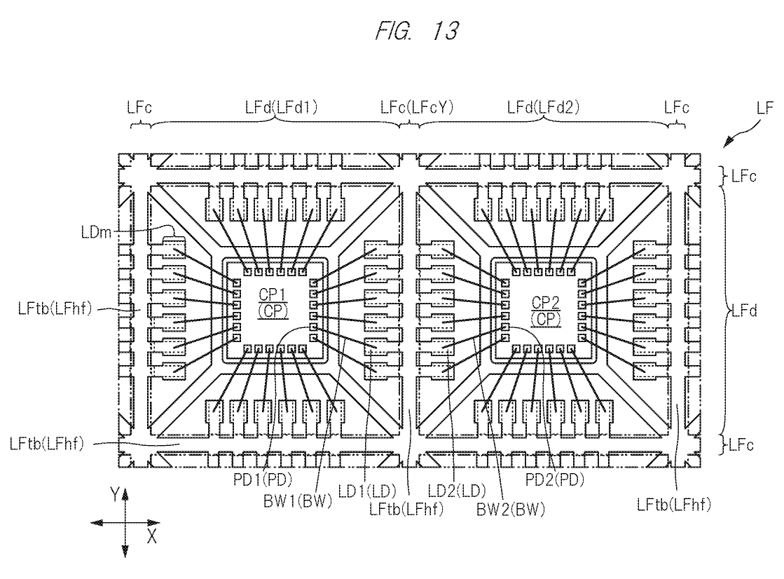

Next, in the wire bonding step illustrated in FIG. 7, as illustrated in FIG. 13, the plurality of pads (electrodes) PD of the semiconductor chip CP and the plurality of leads LD are electrically connected via a plurality of wires (conductive members) BW, respectively. FIG. 13 illustrates an enlarged top view illustrating a state in which the semiconductor chip and the leads illustrated in FIG. 12 are electrically connected via wires.

As illustrated in FIG. 13, in this step, in each of the plurality of device formation portions LFd, the semiconductor chip CP and the leads LD are electrically connected via the wires (conductive members) BW. For example, the leads LD1 of the device formation portion LFd1 are electrically connected to the pads PD1 of the semiconductor chip CP1 via the wires (conductive members) BW1. The leads LD2 of the device formation portion LFd2 are electrically connected to the pads PD2 of the semiconductor chip CP2 via the wires (conductive members) BW2. Although the method of wire bonding is not limited to the following example, one example is described below.

In this step, as illustrated in FIG. 12, the lead frame LF on which the semiconductor chips CP are mounted on the die pads DP of the plurality of device formation portions LFd is arranged on a heat stage (lead frame heating stage) not illustrated.

Next, after connecting a portion (one end portion) of the wire BW to the pad PD of the semiconductor chip CP, another portion (the other end portion) of the wire BW is connected to the wire bonding portion LDm of the lead LD. For example, a plating film made of silver (Ag) or gold (Au) is formed on a portion of the lead LD (the upper surface LDt of the wire bonding portion LDm), and the wire BW is bonded to the plating film.

As described with reference to FIG. 6, the wire bonding portion LDm includes the main body portion LDZ and thin portions LFhf provided on both sides of the main body portion LDZ. A thickness of the main body portion LDZ is greater than a thickness of the thin portions LFhf. Therefore, in consideration of stability on the heat stage, it is preferable that the bonding portion of the wire BW illustrated in FIG. 13 (the above-described other end portion) be entirely bonded to the main body portion LDZ.

However, depending on positional accuracy of a wire bonder for bonding the wire BW, a portion of the wire BW may be bonded to the thin portion LFhf (see FIG. 6). Even when a portion of the bonding portion of the wire BW is bonded to the thin portion LFhf, if another portion thereof is bonded to the main body portion LDZ (see FIG. 6), the wire BW and the wire bonding portion LDm can be stably bonded. In other words, in the present embodiment, since the thin portions LFhf are provided on both sides of the main body portion LDZ, connection reliability between the wire BW and the lead LD can be improved, and a width of the main body portion LDZ can be reduced.

### Sealing Step

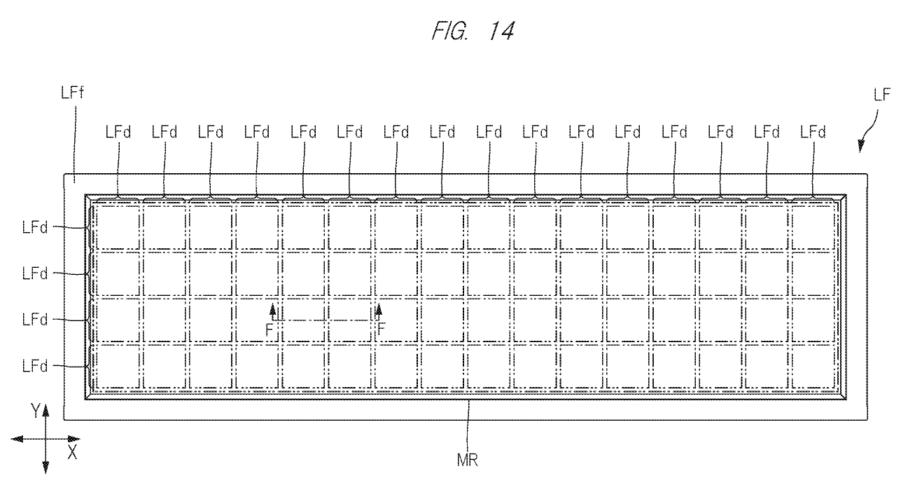

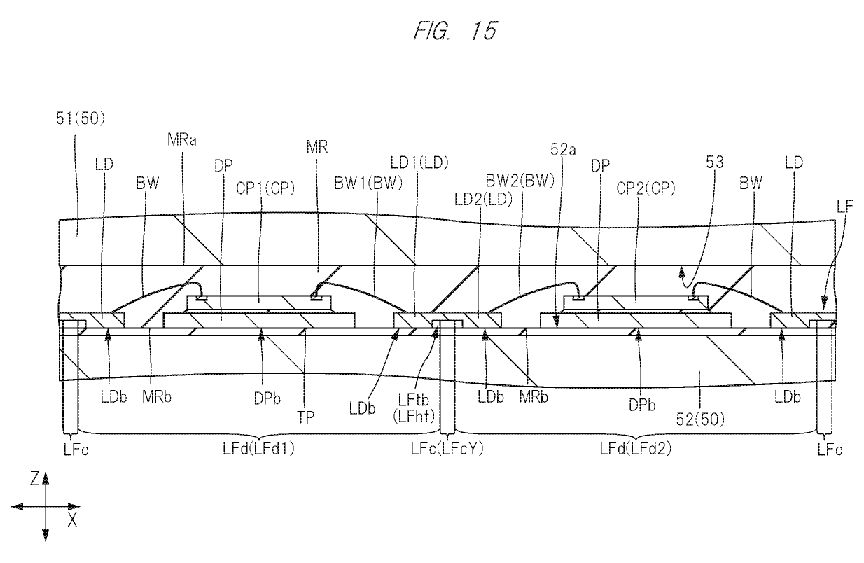

Next, in the sealing step illustrated in FIG. 7, as illustrated in FIG. 15, a sealing body MR is formed to seal a portion of the die pad DP, a portion of each of the plurality of leads LD, the plurality of wires BW, and the semiconductor chip CP. FIG. 14 illustrates a plan view of the sealing body formed in the sealing step illustrated in FIG. 7. FIG. 15 illustrates an enlarged cross-sectional view taken along line F-F in FIG. 14, illustrating a state in which the lead frame is arranged in a cavity of a molding die.

In this step, as illustrated in FIG. 15, a sealing body MR is formed to collectively seal the lead LD1, the lead LD2, the tie bar LFtb, the semiconductor chip CP1, the semiconductor chip CP2, the wire BW1, and the wire BW2. At completion of this step, the lower surface LDb of the lead LD1 and the lower surface LDb of the lead LD2 are exposed from the sealing body MR.

In this step, the sealing body MR illustrated in FIG. 14 is formed by, for example, a transfer molding method described below. In the transfer molding method, for example, in a state in which the lead frame LF is clamped by a molding die 50 illustrated in FIG. 15, a softened sealing resin is transferred under pressure into the molding die 50 and then cured. The sealing resin is made of an insulating material.

The molding die 50 includes an upper die (mold) 51 arranged above the lead frame LF and a lower die (mold) 52 arranged below the lead frame LF. The upper die 51 includes a clamp surface (not illustrated) for pressing the lead frame LF and a cavity (recess) 53 formed inside the clamp surface. The lower die 52 includes a support surface (die surface, pressing surface, surface) 52a arranged to face the cavity 53 and configured to support the lead frame LF. In the present embodiment, since a QFN-type package is manufactured, no cavity is formed in the support surface 52a of the lower die 52.

In the sealing step, the sealing resin is transferred under pressure into the cavity 53 to seal the semiconductor chip CP (see FIG. 15) and the plurality of wires BW (see FIG. 15). In addition, a portion of each of the plurality of leads LD (a portion other than the lower surface LDb) and a portion of the die pad DP (a portion other than the lower surface DPb) are sealed by the sealing resin.

As illustrated in FIG. 15, a tape material (resin film) TP is arranged between the lead frame LF and the lower die 52. A pressing force from the support surface 52a of the lower die 52 is applied to the lower surface side (back surface side, mounting surface side) of the lead frame LF via the tape material TP. Therefore, as illustrated in FIG. 15, the lower surface LDb of the lead LD and the lower surface DPb of the die pad DP tend to closely contact the tape material TP. In other words, in the sealing step of the present embodiment, the sealing body MR is formed in a state in which the tape material closely contacts the lower surface DPb of the die pad DP and the lower surface LDb of each of the plurality of leads LD. By closely contacting the tape material TP, it is possible to suppress the sealing resin from flowing around onto the lower surface LDb of the lead LD and the lower surface DPb of the die pad DP. That is, the lower surface LDb of the lead LD and the lower surface DPb of the die pad DP can be exposed.

Next, the sealing resin supplied into the cavity 53 is thermally cured to form the sealing body MR illustrated in FIG. 14. Specifically, after the sealing body MR is molded by the cavity 53, heating is performed until a portion of the thermosetting resin included in the sealing body MR is cured (this is referred to as temporary curing). When the lead frame LF can be removed from the molding die by the temporary curing, the lead frame LF is removed from the molding die. Thereafter, the lead frame LF is conveyed to a heating furnace and further subjected to heat treatment (cure bake). As a result, the remaining portion of the thermosetting resin is cured, and the sealing body MR is obtained.

In the present embodiment, the sealing body MR is formed so as to collectively seal the plurality of device formation portions LFd. Focusing on the portion illustrated in FIG. 15, the sealing step includes the following steps. The sealing step includes a step of closely contacting one tape material TP across the device formation portion LFd1 and the device formation portion LFd2. The sealing step further includes a step of accommodating the device formation portion LFd1 and the device formation portion LFd2 within one cavity 53. The sealing step further includes a step of supplying resin into the cavity 53 and collectively sealing both the device formation portion LFd1 and the device formation portion LFd2.

The timing at which the tape material TP is brought into close contact with the lead frame LF may be as follows. For example, when an adhesive layer is provided on one surface of the tape material TP, the tape material TP may be attached in advance before arranging the lead frame LF in the cavity 53. Alternatively, the tape material TP may be arranged in advance on the support surface 52a of the lower die 52, and the lead frame LF may be arranged thereon. In this case, the lead frame LF and the tape material TP are pressed and brought into close contact by a supply pressure of the sealing resin.

A semiconductor package in which a sealing body MR is formed so as to collectively cover the plurality of device formation portions LFd arranged in a matrix as in the present embodiment is referred to as a Mold Array Package (MAP) type semiconductor device. A sealing method in which the plurality of device formation portions LFd is collectively sealed is referred to as a block molding method. In the MAP-type semiconductor device, since a separation distance between respective device formation portions LFd can be reduced, an effective area of one lead frame LF increases. That is, the number of products obtainable from one lead frame LF increases. By increasing the effective area of one lead frame LF in this manner, the manufacturing process can be made more efficient. In particular, when several tens of products are obtained from one lead frame LF, the effect of improving manufacturing efficiency due to the increase in effective area is significant.

Here, in this step, as illustrated in FIG. 15, the sealing resin flows around and adheres in regions not closely contacting the molding die 50 or the tape material TP. As described above, the thin portions LFhf are formed in advance in the lead frame LF. The sealing resin flows around the thin portions LFhf and seals them. Therefore, the lower surface TBb of the tie bar LFtb described with reference to FIG. 11 is also sealed in this step.

In the present embodiment, it is necessary to expose the lower surface LDb2 of the stepped portion LDe illustrated in FIG. 3 from the sealing body MR. For this reason, the half dicing step illustrated in FIG. 7 is performed as a step of removing a portion of the sealing body MR (a portion covering the thin portions LFhf illustrated in FIG. 15).

### Half Dicing Step

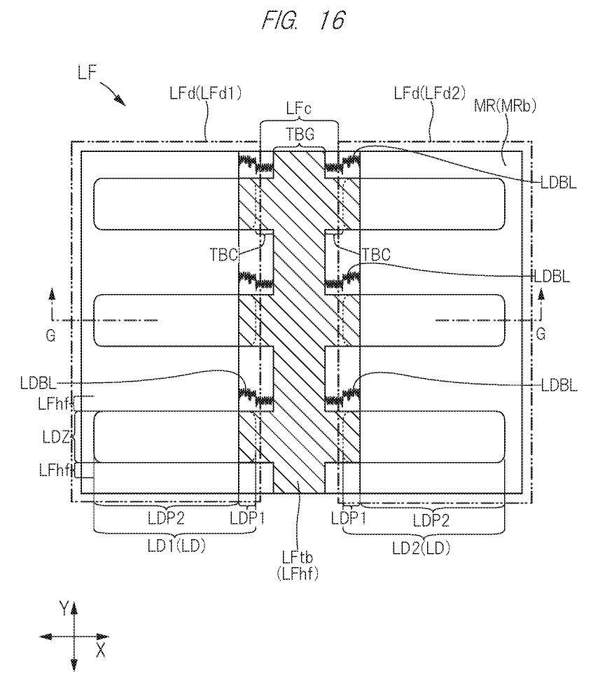

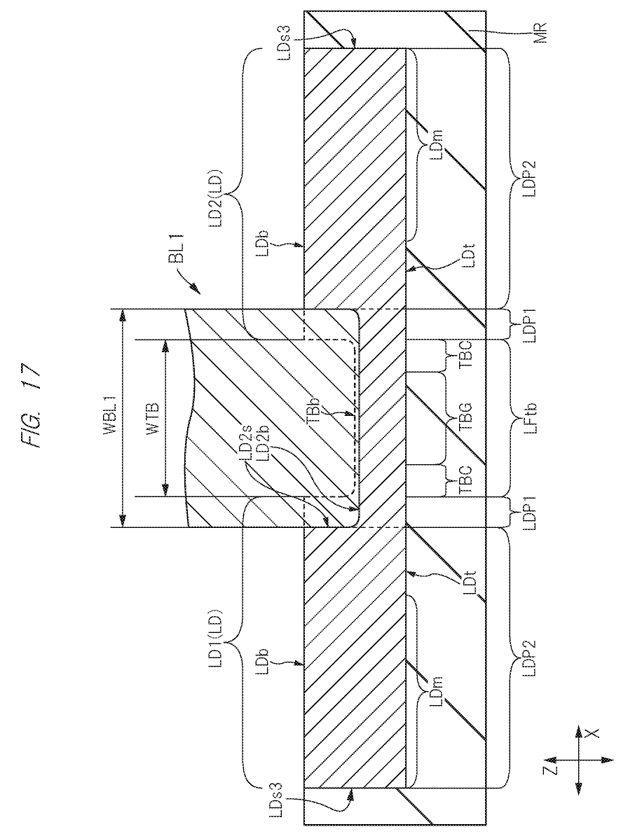

In the half dicing step illustrated in FIG. 7, a portion of the sealing body MR illustrated in FIG. 15 that covers the tie bar LFtb is removed by cutting. In this step, in addition to the sealing body MR, a portion of the lead LD1 (a portion of the portion LDP1) and a portion of the lead LD2 (a portion of the portion LDP1) are removed. Further, in this step, a portion of the tie bar LFtb illustrated in FIG. 11 (a lower layer including an entire lower surface TBb) is removed. FIG. 16 illustrates an enlarged bottom view illustrating a state after completion of the half dicing step illustrated in FIG. 7, in which the sealing body covering the tie bar has been removed. FIG. 17 illustrates an enlarged cross-sectional view taken along line G-G in FIG. 16, illustrating a state during cutting using a blade.

In this step, as illustrated in FIG. 17, cutting is performed using a blade (rotary blade) BL1. This step may also be referred to as a first cutting step. Resin embedded on a lower surface TBb side (see FIG. 17) of the tie bar LFtb is removed by cutting. The blade BL1 is an annular (ring-shaped) or disk-shaped cutting tool in which a plurality of abrasive grains is fixed to a cutting portion arranged on a peripheral edge of a circle. By pressing the cutting portion of the blade BL1, to which the plurality of abrasive grains is fixed, against a portion to be processed, the portion to be processed can be cut and removed.

Further, by this step, the lower surface LDb2 of the stepped portion LDe of the lead LD described with reference to FIG. 3 and the side surface LDs2 continuous with the lower surface LDb2 are formed. That is, the side surface LDs2 is formed by cutting a portion of the lead LD (a portion on the lower surface side of the portion LDP1) with the blade BL1. In FIG. 16, a contour of a remaining portion of the lead LD that is not cut in this step is illustrated by a dashed line.

As illustrated in FIG. 17, a width WBL1 of the blade BL1 used in this step, that is, a cutting width in the half dicing step, is greater than a width WTB of the tie bar LFtb. As a result, in each of the leads LD connected on both sides of the tie bar LFtb, the side surface LDs2 can be formed. In other words, in this step, grooves are formed along the dicing portions LFc by cutting with the blade BL1, thereby forming the stepped portions LDe (see FIG. 3) in each of the plurality of leads LD.

In this step, the tie bar LFtb is not separated. By keeping the leads LD connected to the tie bar LFtb, a metal film can be easily formed by an electrolytic plating method in a metal film formation step described later.

In this step, while rotating the blade BL1 illustrated in FIG. 17, the blade BL1 is moved along the dicing portions LFc (see FIG. 16) of the lead frame LF. As a result, as illustrated in FIG. 16, the stepped portions LDe (see FIG. 3) are formed at peripheral portions of the leads LD along the dicing portions LFc.

A length in the Z direction of the side surface LDs2 (see FIG. 17) formed in this step, that is, a cutting depth, is, for example, half or less of a thickness of the portion LDP2 of the lead LD.

In blade dicing using the blade BL1, which is a rotary blade, a metal burr LDBL (see FIG. 16) extending in a rotation direction of the blade BL1 is formed. A length of the metal burr LDBL (a length in the Y direction in the example illustrated in FIG. 16) is proportional to an amount of metal to be cut.

Therefore, in the Y direction, a length of the metal burr LDBL located on an extension line of the portion LDP1 of the lead LD is greater than a length of the metal burr LDBL located on an extension line of the thin portion LFhf. This is because an amount of metal cut from the thin portion LFhf in this step is smaller than that from the portion LDP1.

Although details will be described later, in the present embodiment, attention is paid to a difference in length of the metal burr LDBL depending on a position of the metal burr LDBL, and by utilizing this difference, adjacent leads LD are prevented from being short-circuited via the metal burr LDBL.

### Metal Film Formation Step

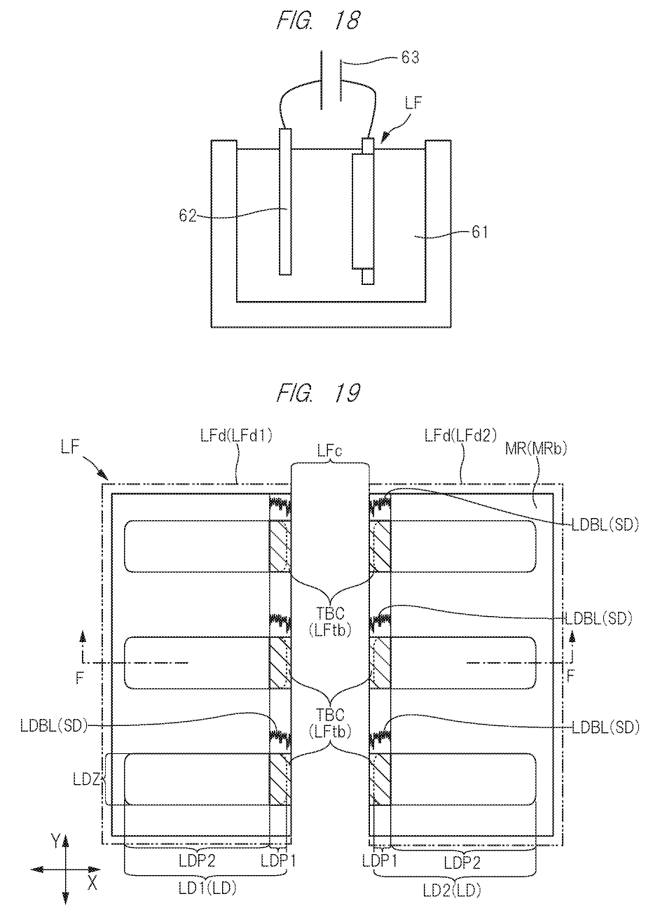

Next, in the metal film formation step illustrated in FIG. 7, after the half dicing step, a metal film SD (see FIG. 3) is formed on portions (exposed surfaces) of the lead frame LF illustrated in FIG. 16 that are exposed from the sealing body MR. FIG. 18 is a schematic explanatory view illustrating an example of the metal film formation step illustrated in FIG. 7.

In this step, for example, as illustrated in FIG. 18, the lead frame LF is immersed in a plating solution 61. The plating solution 61 is, for example, a solder solution. An anode rod 62 is immersed in the plating solution 61. In an electrolytic plating method, the anode rod 62 is used as an anode, and metal portions of the lead frame LF are used as a cathode. Therefore, as illustrated in FIG. 18, the lead frame LF is connected to a negative terminal of a power supply 63, and the anode rod 62 is connected to a positive terminal of the power supply 63. When a current is applied in this state, a reduction reaction occurs on a cathode side, and a metal film SD (see FIG. 22) is formed on surfaces of metal portions of the lead frame LF that are exposed from the sealing body MR.

In the electrolytic plating method, the metal film SD is uniformly formed on portions that are in contact with the plating solution 61 and that constitute a current path. Therefore, in this step, in addition to the lower surface DPb of the die pad DP illustrated in FIG. 9, the lower surface LDb, the side surface LDs2, and the lower surface LDb2 of the lead LD illustrated in FIG. 3, the metal film SD (see FIG. 3) is also formed on a lower surface of the tie bar LFtb.

As illustrated in FIG. 16, the metal burr LDBL is connected to the lead LD or the tie bar LFtb. Therefore, as described above with reference to FIG. 5, the metal film SD is also formed on the metal burr LDBL.

### Singulation Step

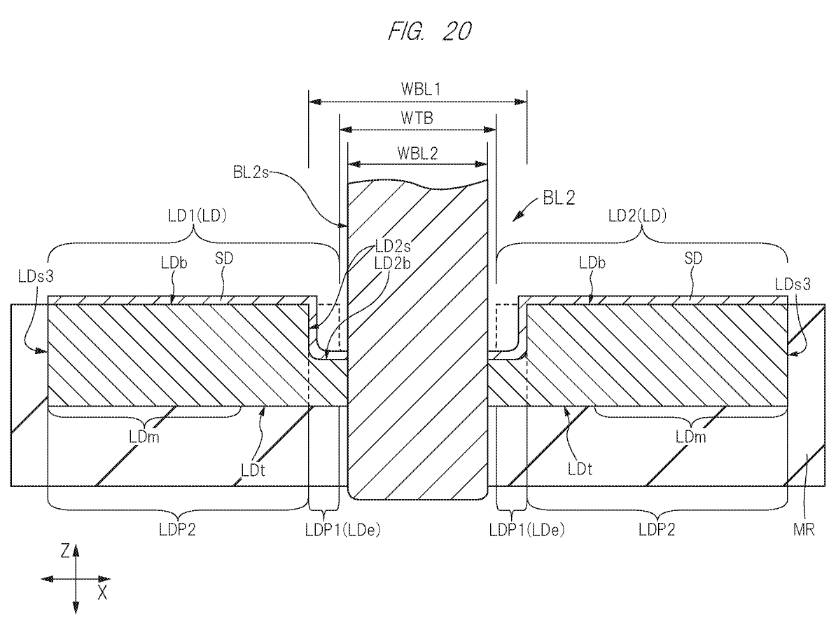

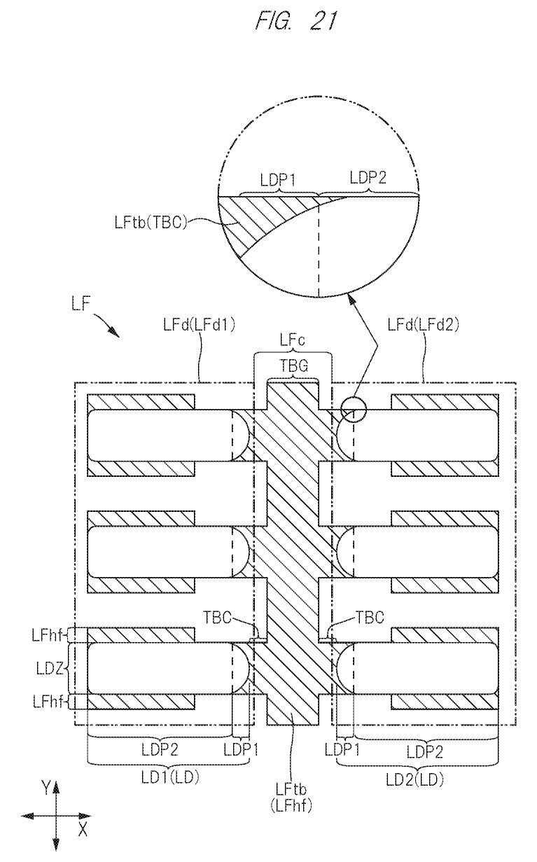

Next, in the singulation step illustrated in FIG. 7, the blade BL2 illustrated in FIG. 20 is moved along the dicing portions LFc illustrated in FIG. 19, thereby dividing and singulating each of the plurality of device formation portions LFd. FIG. 19 illustrates an enlarged bottom view illustrating a state in which two adjacent device formation portions are separated after completion of the singulation step illustrated in FIG. 7. FIG. 20 illustrates an enlarged cross-sectional view illustrating the singulation step illustrated in FIG. 7.

Focusing on the two device formation portions LFd illustrated in FIG. 19, this step can be expressed as follows. That is, in this step, the tie bar LFtb and the sealing body MR (that is, a portion of the sealing body MR) located between the two device formation portions LFd are removed, thereby separating the device formation portion LFd1 and the device formation portion LFd2 from each other. In other words, a remaining portion of the tie bar LFtb that has not been removed in the half dicing step is removed. A width WBL2 of the blade BL2 (see FIG. 20) used in this step is smaller than the width WBL1 of the blade BL1 described with reference to FIG. 17.

The blade BL2 illustrated in FIG. 20 is an annular (ring-shaped) or disk-shaped cutting tool in which a plurality of abrasive grains is fixed to a cutting portion arranged along a circumferential edge of a circle. By pressing the cutting portion of the blade BL2, to which the plurality of abrasive grains is fixed, against a portion to be processed, the portion to be processed can be cut and removed.

The width WBL2 of the blade BL2, in other words, a cutting width of the dicing portion LFc in the singulation step, is equal to or greater than a width of the support portion TBG of the tie bar LFtb illustrated in FIG. 16. Therefore, upon completion of this step, the support portion TBG is removed, and each of the plurality of leads LD is separated from one another.

Here, a metal burr generated when cutting is performed using the blade BL2 will be described. In blade dicing using the blade BL2, which is a rotary blade, a metal burr extending in a rotation direction of the blade BL2 is formed. n this step, all of the lead frame LF and the sealing body MR present in the dicing portion LFc are cut. Therefore, even if a metal burr is formed in the rotation direction of the blade BL2, the metal burr is also removed together with other members.

However, in the vicinity of the portion LDP1 of the lead LD remaining after cutting by the blade BL2, a metal burr LDBL remains, as illustrated in FIG. 19. In the vicinity of a boundary between the dicing portion LFc and the device formation portion LFd, the metal burr LDBL and the metal film SD formed on the metal burr LDBL may come into contact with the blade BL2 (see FIG. 20). In this case, the metal burr LDBL may be stretched in the Y direction by a rotational force of the blade BL2.

When the metal burr LDBL is stretched in the Y direction, there arises a concern that it may come into contact with an adjacent lead LD. Therefore, from the viewpoint of suppressing a short circuit between adjacent leads LD via the metal burr LDBL, it is necessary to shorten the metal burr LDBL that is stretched in the Y direction in this step.

In the present embodiment, in the singulation step, the tie bar LFtb is cut by inserting the blade BL2 illustrated in FIG. 20 between a remaining portion of the portion LDP1 of the lead LD1 and a remaining portion of the portion LDP1 of the lead LD2. A width WBL2 of the blade BL2, in other words, a cutting width of the dicing portion LFc in the singulation step, is equal to or less than a width WTB (see FIG. 20) of the tie bar LFtb including the lead connection portion TBC.

As already described with reference to FIG. 16, a length of the metal burr LDBL (a length in the Y direction in the example illustrated in FIG. 16) is proportional to an amount of metal to be cut. Therefore, in the Y direction, a length of the metal burr LDBL located on an extension line of the portion LDP1 of the lead LD is greater than a length of the metal burr LDBL located on an extension line of the thin portion LFhf. In other words, in the vicinity of a boundary between the dicing portion LFc and the device formation portion LFd, the length of the metal burr LDBL is short.

Even in the present embodiment, in the vicinity of the boundary between the dicing portion LFc and the device formation portion LFd, the metal burr LDBL may be stretched in the Y direction due to a rotational force of the blade BL2 (see FIG. 20). However, since a length of the metal burr LDBL to be stretched is short, it is possible to prevent the metal burr LDBL from reaching the adjacent lead LD.

From the viewpoint of preventing the metal burr LDBL from being excessively stretched, the following configuration is preferable. In the example illustrated in FIG. 20, the width WBL2 of the blade BL2 is smaller than the width WTB. In this case, in the singulation step, the blade BL2 does not contact the remaining portions of the portion LDP1 of each of the lead LD1 and the lead LD2. In other words, contact of the blade BL2 (see FIG. 20) with relatively long portions of the metal burr LDBL illustrated in FIG. 16 is avoided. Accordingly, a length of the metal burr LDBL (see FIG. 19) remaining in the device formation portion LFd after completion of the singulation step can be shortened.

The structure illustrated in FIG. 19 can be expressed as follows. At completion of the singulation step, a portion of the lead connection portion TBC of the tie bar LFtb remains in a state of being connected to a remaining portion of the portion LDP1 of the lead LD1 or the lead LD2. In this state, in the singulation step, the blade BL2 illustrated in FIG. 20 does not contact the remaining portion of the portion LDP1.

Through the above steps, the semiconductor device PKG1 described with reference to FIGS. 1-6 is obtained. Thereafter, as necessary, tests and inspections such as electrical tests and appearance inspections are performed, and those determined to be non-defective are conveyed to subsequent steps such as a packaging step of the semiconductor device.

### First Modification

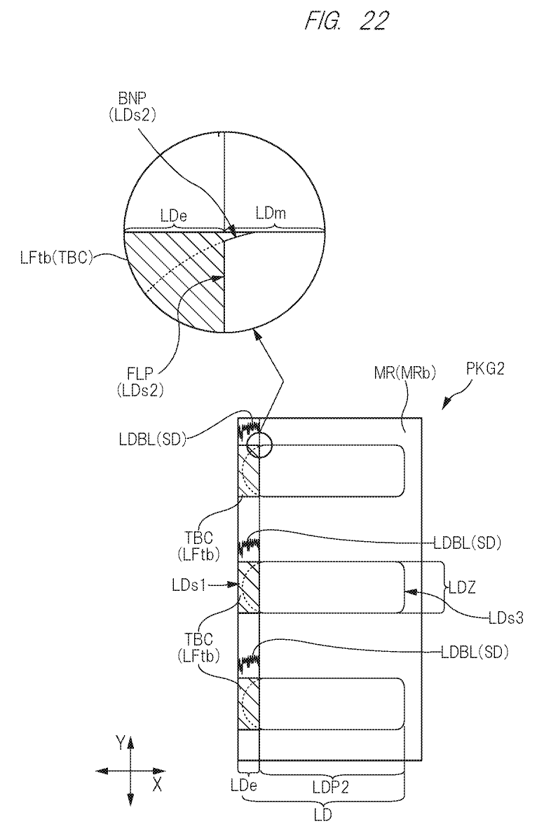

Next, a modification of the above-described embodiment will be described. FIG. 21 is an enlarged bottom view illustrating a modification of FIG. 10. In the case of a lead frame LF2 according to the modification illustrated in FIG. 21, a planar shape of the lead LD differs from that of the lead frame LF illustrated in FIG. 10.

In this modification, in the lead frame preparation step illustrated in FIG. 7, a boundary between the lead LD1 and the lead connection portion TBC of the tie bar LFtb has an arc shape in plan view. Similarly, a boundary between the lead LD2 and the lead connection portion TBC of the tie bar LFtb has an arc shape in plan view.

In this modification, in the half dicing step described with reference to FIG. 7, at least a portion of the portion having the arc shape is removed.

As described above, in order to shorten the length of the metal burr LDBL illustrated in FIG. 16, it is preferable to reduce an amount of metal to be cut in the half dicing step illustrated in FIG. 7.

In this modification, as can be understood by comparing FIGS. 10 and 21, a volume of the portion LDP1 to be cut in the half dicing step is smaller in the lead frame LF2 illustrated in FIG. 21 than in the lead frame LF illustrated in FIG. 10. That is, according to this modification, since a tip shape of the lead LD on the tie bar LFtb side has an arc shape, it is possible to reduce an amount of metal to be cut in the half dicing step.

From the viewpoint of reducing the amount of metal to be cut, it is preferable that the portion LDP1 to be cut in the half dicing step is entirely included in the portion having the arc shape.

In other words, as illustrated in an enlarged manner in FIG. 21, it is preferable that a portion of the portion having the arc shape is included in the portion LDP1 and another portion thereof is included in the portion LDP2.

In other words, it is preferable that the portion having the arc shape extends across a boundary between the portion LDP1 and the portion LDP2.

Although illustration is omitted, as a further modification of this modification, there may be a case where the entire portion having the arc shape is included in the portion LDP1. In this case, compared with this modification, the amount of metal to be cut in the half dicing step increases. Even in this further modification, since the portion having the arc shape is included in the portion LDP1, the amount of metal to be cut in the half dicing step can be reduced compared with the lead frame LF illustrated in FIG. 10.

As illustrated in FIG. 21, in the modification in which the portion having the arc shape extends across the boundary between the portion LDP1 and the portion LDP2, a shape of a semiconductor device obtained differs from that of the semiconductor device PKG1 described with reference to FIGS. 1-6 in the following point. FIG. 22 is an enlarged bottom view illustrating a lead of a semiconductor device manufactured using the lead frame illustrated in FIG. 21.

In this modification, of the portion having the arc shape illustrated in FIG. 21, a portion included in the portion LDP1 is cut in the half dicing step. On the other hand, a portion included in the portion LDP2 is not cut in the half dicing step. Accordingly, as illustrated in FIG. 22, in the lead LD of a semiconductor device PKG2, a structure around the stepped portion LDe is as follows.

Each of the plurality of leads LD includes a main body portion LDZ and a stepped portion LDe. The main body portion LDZ includes a side surface LDs3 facing the die pad DP (see FIG. 3) and a side surface LDs2 located opposite the side surface LDs3. The side surface LDs2 includes a flat surface portion FLP extending in the Y direction, which is an arrangement direction of the plurality of leads LD, and a curved surface portion BNP that is continuous with the flat surface portion FLP and has an arc shape in plan view.

Although not illustrated in FIG. 22, the metal film SD illustrated in FIG. 3 is formed on the side surface LDs2.

With respect to the semiconductor device PKG2 illustrated in FIG. 22, when a technical concept is extracted, it can be expressed as follows. That is, the semiconductor device PKG2 includes:

a die pad;

a plurality of leads including a first upper surface and a first lower surface located opposite the first upper surface, the plurality of leads arranged apart from the die pad;

a semiconductor chip mounted on the die pad;

a plurality of conductive members electrically connecting the semiconductor chip and the plurality of leads; and

a sealing body including a second upper surface and a second lower surface located opposite the second upper surface, the sealing body sealing a portion of the die pad, a portion of each of the plurality of leads, the plurality of conductive members, and the semiconductor chip such that the first lower surface of each of the plurality of leads is exposed from the second lower surface,

in which each of the plurality of leads includes:

a main body portion including the first upper surface and the first lower surface; and

a stepped portion arranged at a position farther from the die pad than the main body portion and having a thickness smaller than that of the main body portion,

in which the plurality of leads is arranged in a first direction,

in which the stepped portion includes the first upper surface and a third lower surface located opposite the first upper surface,

in which the main body portion includes:

a first side surface facing the die pad; and

a second side surface located opposite the first side surface, and

in which the second side surface includes:

a flat surface portion extending in the first direction; and

a curved surface portion continuous with the flat surface portion and having an arc shape in plan view.

### Second Modification

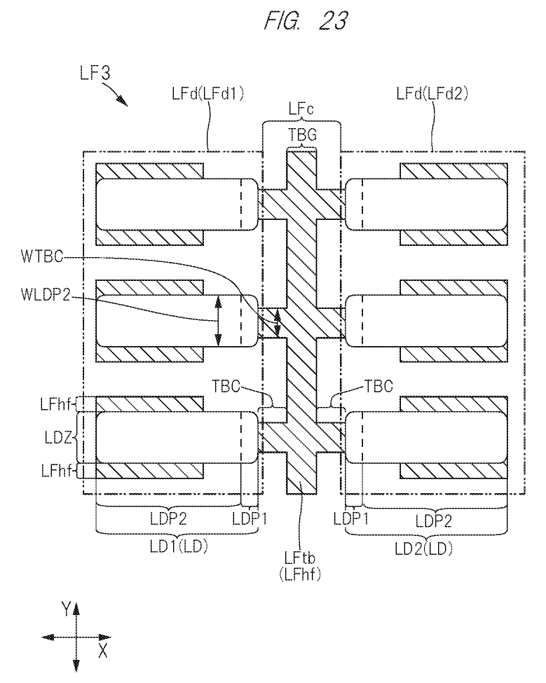

Next, another modification relating to the shape of the lead frame will be described. FIG. 23 is an enlarged bottom view illustrating another modification of FIG. 10. The lead frame LF3 illustrated in FIG. 23 differs from the lead frame LF illustrated in FIG. 10 in the following point.

That is, a width WTBC of the lead connection portion TBC of the tie bar LFtb of the lead frame LF3 is smaller than a width WLDP2 of the portion LDP2 of each of the lead LD1 and the lead LD2.

As described above, the metal burr LDBL (see FIG. 16) formed by cutting in the half dicing step becomes longer in proportion to an amount of metal to be cut. In this modification, compared with the lead frame LF illustrated in FIG. 10, the width WTBC of the lead connection portion TBC is smaller. In other words, in this modification, focusing on the lead connection portion TBC, an amount of metal to be cut in the half dicing step is smaller than that in the embodiment illustrated in FIG. 10. Therefore, in this modification, a length of the metal burr extending from the lead connection portion TBC is shorter than that in the example illustrated in FIG. 16.

Accordingly, in this modification, compared with a case where the lead frame LF illustrated in FIG. 10 is used, the length of the metal burr can be further shortened.

### Other Modifications

In addition to the above modifications, the above-described technique can be applied to various modifications. For example, in the above embodiment and modifications, as an example of the semiconductor device, a QFN-type semiconductor device in which a plurality of leads is arranged on each of four sides of the semiconductor device has been described. However, an arrangement manner of the plurality of leads is not limited to the QFN type. For example, the technique can be applied to a DFN-type semiconductor device in which a plurality of leads LD is arranged only on two sides of the four sides of the semiconductor device that are opposite to each other.

In the above embodiment, it has been described that, in the half dicing step, not only a portion of the lead LD2 (a portion of the portion LDP1) but also a portion of the tie bar LFtb is removed. As a modification of the above embodiment, there may be a case where the tie bar LFtb is not removed in the half dicing step. However, when a part of the tie bar LFtb is not removed in the half dicing step, the sealing body MR covering the lower surface TBb of the tie bar LFtb is also not removed. On the other hand, there may be a case where a position of the blade BL2 used in the subsequent singulation step is shifted from an original position toward one of two adjacent device formation portions LFd. In this case, the sealing body MR covering the lower surface TBb of the tie bar LFtb (in particular, the lead connection portion TBC) is not removed even in the singulation step. As a result, the sealing body MR that has not been removed may later become foreign matter and may fall off or scatter. In view of this point, in the half dicing step, it is preferable to remove not only a portion of the lead LD2 but also a portion of the tie bar LFtb, as in the above embodiment. Accordingly, the sealing body MR covering the lower surface TBb of the tie bar LFtb can also be removed in the half dicing step.

Although the invention made by the present inventor has been specifically described above based on the embodiment, the present invention is not limited to the above embodiment, and it goes without saying that various modifications can be made without departing from the gist thereof.

What is claimed is:

1. A method of manufacturing a semiconductor device, comprising steps of:
(a) preparing a lead frame including:
a first lead provided in a first device formation portion,
a second lead provided in a second device formation portion located adjacent to the first device formation portion, and
a tie bar provided in a dicing portion between the first device formation portion and the second device formation portion, the tie bar being connected to each of the first lead and the second lead;
(b) after the step of (a), mounting a first semiconductor chip on the first device formation portion, and mounting a second semiconductor chip on the second device formation portion;
(c) after the step of (b), electrically connecting the first lead and the first semiconductor chip to each other via a first conductive member, and electrically connecting the second lead and the second semiconductor chip to each other via a second conductive member;
(d) after the step of (c), forming a sealing body that collectively seals the first lead, the second lead, the tie bar, the first semiconductor chip, the second semiconductor chip, the first conductive member, and the second conductive member such that a lower surface of each of the first lead and the second lead is exposed;
(e) after the step of (d), removing a portion of each of the first lead and the second lead using a first blade having a first width greater than a width of the tie bar;
(f) after the step of (e), forming a metal film by a plating method on an exposed surface of the lead frame that is exposed from the sealing body; and
(g) after the step of (f), removing the tie bar and the sealing body using a second blade having a second width smaller than the first width, thereby separating the first device formation portion and the second device formation portion from each other,
wherein the tie bar of the lead frame prepared in the step of (a), includes:
a lead connection portion extending in a first direction from the first lead toward the second lead in plan view; and
a support portion extending in a second direction intersecting the first direction in plan view,
wherein, in the step of (a), with an upper surface of each of the first lead and the second lead serving as a reference plane, a height difference between a lower surface of the tie bar and the reference plane is smaller than a height difference between the lower surface of each of the first lead and the second lead and the reference plane,
wherein each of the first lead and the second lead of the lead frame prepared in the step of (a), includes:
a first portion having the portion removed by the first blade in the step of (e); and
a second portion that is not removed in the step of (e), and
wherein, in the step of (g), the tie bar is cut by inserting the second blade between a remaining portion of the first portion of the first lead and a remaining portion of the first portion of the second lead.

2. The method of manufacturing a semiconductor device according to claim 1,
wherein, in the step of (g), the second blade does not contact the remaining portion of the first portion of each of the first lead and the second lead.

3. The method of manufacturing a semiconductor device according to claim 1,
wherein, upon completion of the step of (g), a portion of the lead connection portion of the tie bar is connected to at least the remaining portion of the first portion of the first lead or the remaining portion of the first portion of the second lead.

4. The method of manufacturing a semiconductor device according to claim 1,
wherein, in the step of (a), a boundary between the first lead and the lead connection portion of the tie bar and a boundary between the second lead and the lead connection portion of the tie bar each have an arc shape in plan view.

5. The method of manufacturing a semiconductor device according to claim 4,
wherein, in the step of (e), a part of a portion having the arc shape is removed.

6. The method of manufacturing a semiconductor device according to claim 4,
wherein the portion having the arc shape extends across a boundary between the first portion and the second portion.

7. The method of manufacturing a semiconductor device according to claim 1,
wherein, in the step of (a), a thickness of the tie bar is half or less of a thickness of each of the first lead and the second lead.

8. The method of manufacturing a semiconductor device according to claim 1,
wherein each of the first blade and the second blade is a rotary blade,
wherein, in the step of (e), a metal burr extending in a rotation direction of the first blade is formed from each of the first portion of the first lead and the first portion of the second lead, and
wherein, in the step of (f), the metal film is also formed on the metal burr.

9. The method of manufacturing a semiconductor device according to claim 1,
wherein a width of the lead connection portion of the tie bar of the lead frame prepared in the step of (a) is smaller than a width of the second portion of each of the first lead and the second lead.
